(19) United States
(12) Patent Application Publication
(10) Pub. No.: US 2018/0307931 A1
(43) Pub. Date: Oct. 25, 2018

(54) IMPRINTING SYSTEM AND METHOD FOR FINGERPRINT SENSOR

(71) Applicant: Primax Electronics Ltd., Taipei (TW)

(72) Inventor: CHIH-HAO HSU, Taipei (TW)

(21) Appl. No.: 15/701,658

(22) Filed: Sep. 12, 2017

(30) Foreign Application Priority Data
Apr. 21, 2017 (TW) 106113495

(51) Int. Cl. G06K 9/20; G06K 9/00; H01L 23/48; H01L 21/56; H05K 1/02

(52) U.S. Cl. CPC G06K 9/209; G06K 9/00053; G06K 9/0002; H01L 21/56; H05K 1/0298; H01L 23/481

(57) ABSTRACT

A fingerprint sensor imprinting system includes a first fixture, an imprinting module, a laser cutting module, an air pump and a second fixture. The first fixture includes an opening for accommodating a fingerprint sensor. The imprinting module forms an imprinted layer on the first fixture and the fingerprint sensor. The laser cutting module cuts the imprinted layer to define a protective layer on the top surface of the fingerprint sensor. The second fixture has a recess for accommodating the fingerprint sensor. After the fingerprint sensor is transferred to the recess, the air pump is enabled to drive the vacuum adsorption unit to adsorb the fingerprint sensor, and then the protective layer is cut such that the area of the protective layer is equal to the area of the top surface of the fingerprint sensor.

### FIELD OF THE INVENTION

The present invention relates to an imprinting technology, and more particularly to an imprinting system and an imprinting method for an electronic device.

### BACKGROUND OF THE INVENTION

Recently, a fingerprint identification module has been an essential component of an electronic device. The fingerprint identification module is used to recognize the identity of the user. Consequently, the user can unlock or control the electronic device through the fingerprint identification module.

Generally, the fingerprint identification module comprises a fingerprint sensor and a protective layer. The protective layer is placed on the fingerprint sensor. When the fingerprint of the user presses the protective layer, the fingerprint sensor detects the user's fingerprint that is contacted with the protective layer.

In accordance with the conventional method, an imprinted layer is formed on the surfaces of a batch of fingerprint sensors, and then the imprinted layer is laser-cut into individually fingerprint sensors with protective layers. However, the batch processing method may result in many drawbacks. For example, in case that the imprinted layer is not uniformly coated, the boundary of the imprinted layer is possibly overflowed or burred. Under this circumstance, the surface of the protective layer of the fingerprint sensor is neither smooth nor glossy. Consequently, the delicate tactile feel is lost.

For solving the drawbacks of the conventional technologies, the present invention provides an imprinting system and an imprinting method for preventing the overflowed or burred problem of the imprinted layer.

### SUMMARY OF THE INVENTION

In accordance with an aspect of the present invention, there is provided a fingerprint sensor imprinting system for imprinting a fingerprint sensor. The fingerprint sensor has a top surface and a bottom surface. The fingerprint sensor imprinting system includes a first fixture, an imprinting module, a laser cutting module, an air pump and a second fixture. The first fixture includes a first surface, a second surface and at least one opening. The second surface is opposed to the first surface. The at least one opening is formed in the second surface. The fingerprint sensor is accommodated within the at least one opening. The imprinting module forms an imprinted layer on the second surface of the first fixture and the top surface of the fingerprint sensor. The laser cutting module cuts the imprinted layer to define a protective layer on the top surface of the fingerprint sensor. An area of the protective layer is larger than an area of the top surface. The second fixture has a recess for accommodating the fingerprint sensor. A vacuum adsorption unit is located at a side of the recess. The vacuum adsorption unit is connected with the air pump. After the fingerprint sensor is transferred from the at least one opening of the first fixture to the recess of the second fixture, the air pump is enabled to drive the vacuum adsorption unit to adsorb and fix the fingerprint sensor, and then the protective layer is cut by the laser cutting module. Consequently, the area of the protective layer is equal to the area of the top surface.

In an embodiment, the at least one opening runs through the first surface and the second surface.

In an embodiment, the first fixture further includes an adhesive layer. The adhesive layer is disposed on the first surface. The bottom surface of the fingerprint sensor is adhered onto the adhesive layer.

In an embodiment, the imprinted layer is an optically-cured ink layer, a thermally-cured ink layer, a mixed ink layer, a UV-cured resin layer or an anti-fingerprint coating layer.

In an embodiment, the imprinting module includes a coating unit and an imprinting unit.

In an embodiment, the coating unit is a coating knife or a coating roller.

In an embodiment, the imprinting unit is an imprinting plate or an imprinting roller.

In accordance with another aspect of the present invention, there is provided a fingerprint sensor imprinting method. In a step (a), a fingerprint sensor is provided, wherein the fingerprint sensor has a top surface and a bottom surface. In a step (b), a first fixture is provided. The first fixture includes a first surface, a second surface and at least one opening. The second surface is opposed to the first surface. The at least one opening is formed in the second surface. In a step (c), the fingerprint sensor is placed within the at least one opening, and an imprinted layer is formed on the top surface of the fingerprint sensor and the second surface of the first fixture. In a step (d), the imprinted layer is cut to define a protective layer, wherein an area of the protective layer is larger than an area of the top surface. In a step (e), a second fixture is provided. The second fixture has a recess. A vacuum adsorption unit is located at a side of the recess. In a step (f), the fingerprint sensor is transferred to the recess of the second fixture, and the vacuum adsorption unit is driven to adsorb and fix the fingerprint sensor. In a step (g), the protective layer is cut such that the area of the protective layer is equal to the area of the top surface.

Preferably, in the step (c), an ink material is coated and imprinted on the top surface of the fingerprint, so that the imprinted layer is formed.

In an embodiment, the ink material is an optically curable ink material, a thermally curable ink material, or a mixed ink material with the optically curable ink material and the thermally curable ink material.

Preferably, in the step (c), a UV-curable resin material is coated and imprinted on the top surface of the fingerprint, so that the imprinted layer is formed.

Preferably, in the step (c), an anti-fingerprint coating is coated and imprinted on the top surface of the fingerprint, so that the imprinted layer is formed.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic block diagram illustrating the architecture of a fingerprint sensor imprinting system according to an embodiment of the present invention;

FIGS. 2A˜2G schematically illustrate a process of forming a protective layer on a top surface of a fingerprint sensor according to an embodiment of the present invention;

FIGS. 3A˜3C schematically illustrate a process of trimming the protective layer of the fingerprint sensor according to an embodiment of the present invention; and

FIG. 4 is a flowchart illustrating a fingerprint sensor imprinting method according to an embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

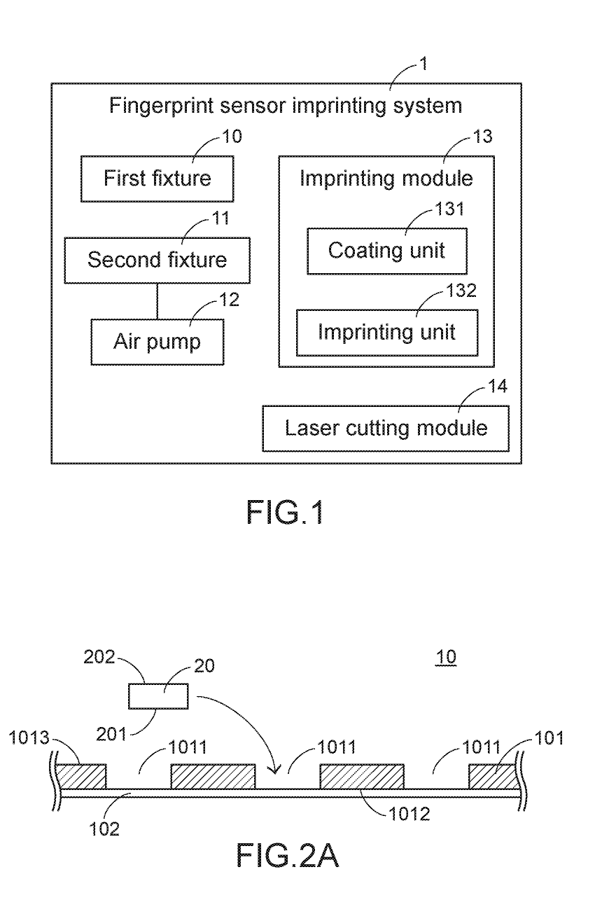

FIG. 1 is a schematic block diagram illustrating the architecture of a fingerprint sensor imprinting system according to an embodiment of the present invention. As shown in FIG. 1, the fingerprint sensor imprinting system 1 comprises a first fixture 10, a second fixture 11, an air pump 12, an imprinting module 13 and a laser cutting module 14. The second fixture 11 is connected with the air pump 12. During the operation of the air pump 12, the air within the second fixture 11 is evacuated. Consequently, the second fixture 11 provides the vacuum adsorption efficacy. The imprinting module 13 comprises a coating unit 131 and an imprinting unit 132. For example, the coating unit 131 is a coating knife or a coating roller, and the imprinting unit 132 is an imprinting plate or an imprinting roller.

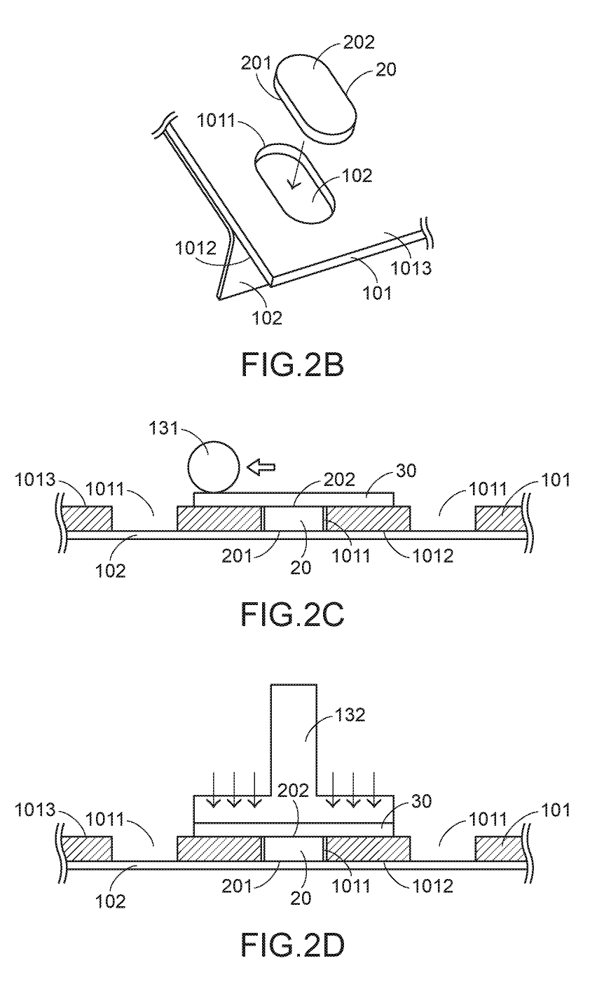

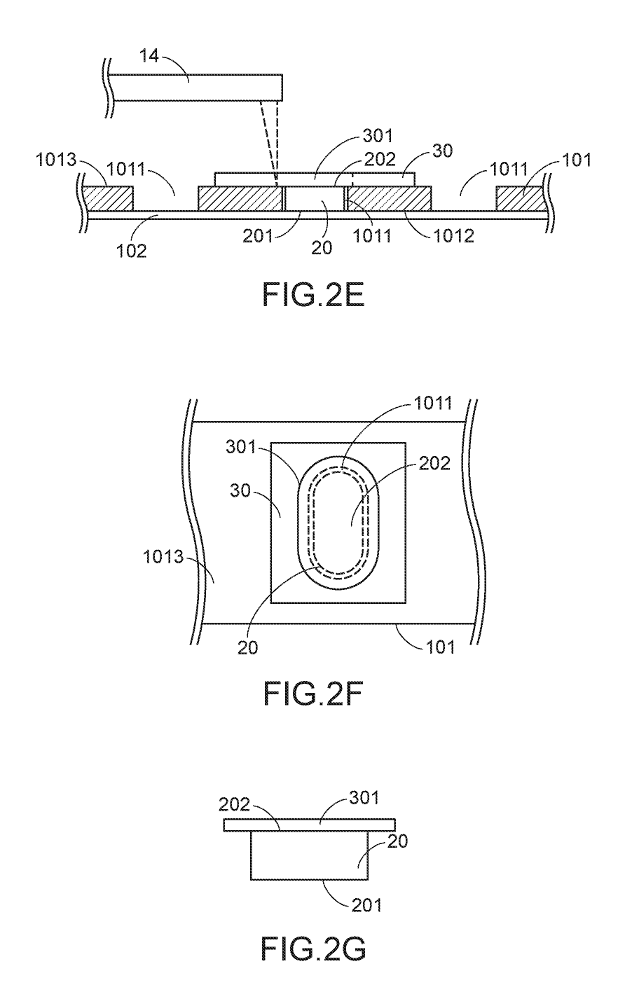

Please refer to FIGS. 2A˜2G FIGS. 2A˜2G schematically illustrate a process of forming a protective layer on a top surface of a fingerprint sensor according to an embodiment of the present invention.

As shown in FIG. 2A, the first fixture 10 comprises a first fixture plate 101 and an adhesive layer 102. The adhesive layer 102 is an adhesive paper that withstands high temperature. Consequently, the adhesive layer 102 still has a certain sticky property at a high temperature. The fixture plate 101 comprises a first surface 1012, a second surface 1013 and plural openings 1011. The openings 1011 run through the first surface 1012 and the second surface 1013. The adhesive layer 102 is disposed on the first surface 1012 and attached on the first surface 1012. The openings 1011 are used for accommodating fingerprint sensors 20.

In the perspective view of FIG. 2B, a fingerprint sensor 20 is being placed in a corresponding opening 1011. The adhesive layer 102 is disposed on the first surface 1012 and adhered onto a bottom surface 201 of the fingerprint sensor 20. Consequently, the fingerprint sensor 20 is fixed on the adhesive layer 102. Moreover, the adhesive layer 102 may be attached on the first surface 1012 or removed from the first surface 1012. After the protective layer of the fingerprint sensor 20 is formed, the adhesive layer 102 is removed. Consequently, the user may remove the fingerprint sensor 20 from the opening 1011 more easily. In an embodiment, the fingerprint sensor 20 has a land grid array (LGA) structure. Moreover, the fingerprint sensor 20 comprises a substrate (not shown), a sensing chip (not shown) and an epoxy molding compound (EMC) material (not shown). The sensing chip is electrically connected with the substrate. The substrate and the sensing chip are encapsulated by the EMC material. After packaged, the fingerprint sensor 20 has the bottom surface 201 and a top surface 202.

Then, as shown in FIG. 2C, the fingerprint sensor 20 is placed in the opening 1011. Meanwhile, the bottom surface 201 of the fingerprint sensor 20 is adhered onto the adhesive layer 102, and the fingerprint sensor 20 is temporarily fixed in the opening 1011. The top surface 201 of the fingerprint sensor 20 is slightly higher or slightly lower than the second surface 1013 of the first fixture 101, or the top surface 201 of the fingerprint sensor 20 is at the same level with the second surface 1013 of the first fixture 101. Then, an ink material, a UV-curable resin material or an anti-fingerprint coating is coated on the top surface 202 of the fingerprint sensor 20 and a portion of the second surface 1013 of the first fixture 101 by the coating unit 131. Consequently, a coated layer 30 is formed.

Please refer to FIG. 2D. After the coating step is completed by the coating unit 131, the imprinting unit 132 is used to imprint the coated layer 30. During the imprinting step, the coated layer 30 is also treated with a thermally-baking processor or an ultraviolet exposing process. Consequently, the coated layer 30 is cured and formed as an imprinted layer 30 with a high-gloss surface. The high-gloss surface is an optically-oily or shiny surface with high fineness. The ink material is an optically curable ink material, a thermally curable ink material, or a mixed ink material with the optically curable ink material and the thermally curable ink material. The UV-curable resin material is a low molecular polymer composed of monomer and oligomer. After the UV-curable resin material is irradiated with UV light, the UV-curable resin material undergoes physical and chemical changes in a short time. Consequently, the UV-curable resin material is crosslinked and cured quickly. Depending on the types of the coating material, the imprinted layer 30 formed through the thermally-baking processor or the ultraviolet exposing process is an optically-cured ink layer, a thermally-cured ink layer, or a mixed ink layer, a UV-cured resin layer, an anti-fingerprint coating layer or the combination thereof.

Please refer to FIG. 2E. After the imprinted layer 30 is formed, the laser cutting module 14 is used for cutting the imprinted layer 30. Consequently, a protective layer 301 is formed on the top surface 202 of the fingerprint sensor 20.

Please refer to FIGS. 2F and 2G. In the top view of FIG. 2F, the top surface 202 of the fingerprint sensor 20 is completely covered by the protective layer 301. The area of the protective layer 301 is larger than the area of the top surface 202 of the fingerprint sensor 20. In the side view of FIG. 2G, the fingerprint sensor 20 is removed from the opening 1011. After the imprinted layer 30 is cut, the top surface 202 of the fingerprint sensor 20 is completely covered by the protective layer 301. Moreover, the area of the protective layer 301 is larger than the area of the top surface 202 of the fingerprint sensor 20. In case that the top surface 202 of the fingerprint sensor 20 is at the same level with the second surface 1013 of the first fixture 101, the thickness of the protective layer 301 is equal to the thickness of the imprinted layer 30. In case that the top surface 202 of the fingerprint sensor 20 is slightly lower than the second surface 1013 of the first fixture 101, the protective layer 301 is slightly thicker than the imprinted layer 30. In case that the top surface 202 of the fingerprint sensor 20 is slightly higher than the second surface 1013 of the first fixture 101, the protective layer 301 is slightly thinner than the imprinted layer 30.

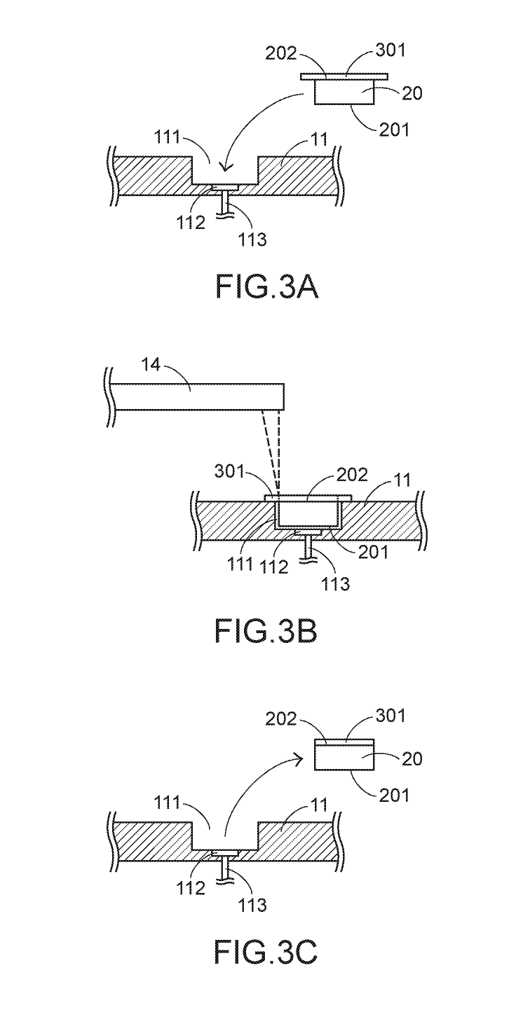

Please refer to FIG. 1 and FIGS. 3A˜3C. FIGS. 3A˜3C schematically illustrate a process of trimming the protective layer of the fingerprint sensor according to an embodiment of the present invention.

Please refer to FIG. 3A. The second fixture 11 comprises a recess 111. The fingerprint sensor 20 with the protective layer 301 can be accommodated within the recess 111. The second fixture 11 further comprises a vacuum adsorption unit 112 and a communication tube 113, which are located at a bottom side of the recess 111. The vacuum adsorption unit 112 is in communication with the communication tube 113. A first end of the communication tube 113 is connected with the vacuum adsorption unit 112. A second end of the communication tube 113 is connected with the air pump 12 (see FIG. 1).

Please refer to FIG. 3B. Then, the fingerprint sensor 20 with the protective layer 301 is accommodated within the recess 111. After the air pump 12 is activated, the air in the vacuum adsorption unit 112 and the communication tube 113 is evacuated by the air pump 12. The vacuum adsorption unit 112 provides the vacuum adsorption efficacy to adsorb the bottom surface 201 of the fingerprint sensor 20. Consequently, the fingerprint sensor 20 is fixed in the recess 111. Then, the laser cutting module 14 is used to cut the undesired portion of the protective layer 301. Meanwhile, the area of the protective layer 301 is equal to the area of the top surface 202 of the fingerprint sensor 20.

Please refer to FIG. 3C. After the protective layer 301 is cut and trimmed and thus the area of the protective layer 301 is equal to the area of the top surface 202 of the fingerprint sensor 20, the air pump 12 is disabled. Meanwhile, the vacuum adsorption unit 112 no longer provides the vacuum adsorption efficacy. Then, the fingerprint sensor 20 is removed from the recess 111. Preferably, after the protective layer 301 is cut and trimmed, the air pump 12 provides air to the vacuum adsorption unit 112 through the communication tube 113. The air ejected from the vacuum adsorption unit 112 may directly remove the fingerprint sensor 20 from the recess 111 or facilitate removing the fingerprint sensor 20 from the recess 111. In this embodiment, the vacuum adsorption unit 112 is located under the recess 111. It is noted that the position of the vacuum adsorption unit 112 is not restricted. For example, in another embodiment, the vacuum adsorption unit 112 is located at any sidewall of the recess 111.

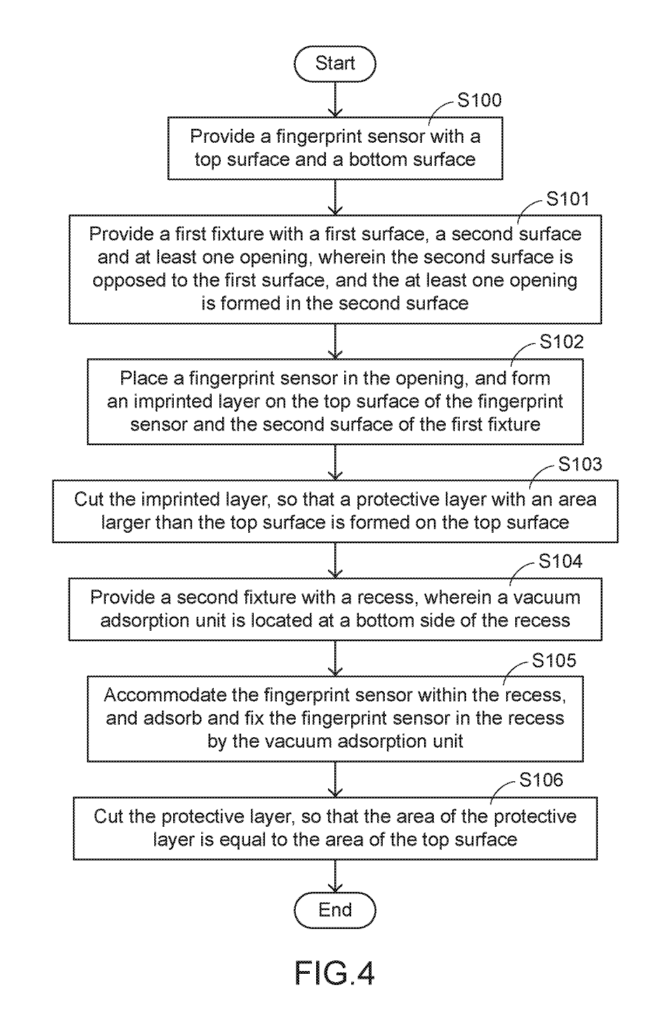

Please refer to FIG. 1, FIGS. 2A˜2G, FIGS. 3A˜3C and FIG. 4. FIG. 4 is a flowchart illustrating a fingerprint sensor imprinting method according to an embodiment of the present invention. Firstly, a fingerprint sensor 20 is provided, wherein the fingerprint sensor 20 comprises a top surface 202 and a bottom surface 201 (Step S100). Then, a first fixture 10 with a first surface 1012, a second surface 1013 and at least one opening 1011 is provided, wherein the second surface 1013 is opposed to the first surface 1012, and the at least one opening 1011 is formed in the second surface 1013 (Step S101). In the step S101, the first fixture 10 comprises a first fixture plate 101 and an adhesive layer 102. The first fixture plate 101 has the at least one opening 1011, which runs through the first surface 1012 and the second surface 1013. The adhesive layer 102 is disposed on the first surface 1012 and attached on the first surface 1012. Then, a fingerprint sensor 20 is placed in the opening 1011, and an imprinted layer 30 is formed on the top surface 202 of the fingerprint sensor 20 and the second surface 1013 of the first fixture 101 (Step S102). In the step S102, an ink material, a UV-curable resin material or an anti-fingerprint coating is coated on the top surface 202 of the fingerprint sensor 20 and the second surface 1013 of the first fixture 101 by a coating unit 131. Consequently, a coated layer 30 is formed. After the coating step is completed, an imprinting unit 132 is used to imprint the coated layer 30. During the imprinting step, the coated layer 30 is also treated with a thermally-baking processor or an ultraviolet exposing process. Consequently, the coated layer 30 is cured and formed as an imprinted layer 30. The ink material is an optically curable ink material, a thermally curable ink material, or a mixed ink material with the optically curable ink material and the thermally curable ink material. The UV-curable resin material is a low molecular polymer composed of monomer and oligomer. After the UV-curable resin material is irradiated with UV light, the UV-curable resin material is crosslinked and cured quickly in a short time. Depending on the types of the coating material, the imprinted layer 30 formed through the thermally-baking processor or the ultraviolet exposing process is an optically-cured ink layer, a thermally-cured ink layer, or a mixed ink layer, a UV-cured resin layer, an anti-fingerprint coating layer or the combination thereof.

Then, the laser cutting module 14 is used for cutting the imprinted layer 30, so that a protective layer 301 with an area larger than the top surface 202 of the fingerprint sensor 20 is formed on the top surface 202 (Step S103). Then, a second fixture 11 with a recess 111 is provided, wherein a vacuum adsorption unit 112 is located at a bottom side of the recess 111 (Step S104). In the step S104, the second fixture 11 further comprises a communication tube 113. The vacuum adsorption unit 112 and the communication tube 113 are located under the recess 111. The vacuum adsorption unit 112 is in communication with the communication tube 113. A first end of the communication tube 113 is connected with the vacuum adsorption unit 112. A second end of the communication tube 113 is connected with the air pump 12. Then, the fingerprint sensor 20 is accommodated within the recess 111, and the fingerprint sensor 20 is adsorbed and fixed in the recess 111 by the vacuum adsorption unit 112 (Step S105). In the step S105, the fingerprint sensor 20 with the protective layer 301 is accommodated within the recess 111. Then, the air pump 12 is activated, and the air in the vacuum adsorption unit 112 and the communication tube 113 is evacuated by the air pump 12. The vacuum adsorption unit 112 provides the vacuum adsorption efficacy to adsorb the bottom surface 201 of the fingerprint sensor 20. Consequently, the fingerprint sensor 20 is fixed in the recess 111. Then, a laser cutting module 14 is used to cut the undesired portion of the protective layer 301, so that the area of the protective layer 301 is equal to the area of the top surface 202 of the fingerprint sensor 20 (Step S106). In the step S106, the air pump 12 is disabled after the protective layer 301 is cut and trimmed and the area of the protective layer 301 is equal to the area of the top surface 202 of the fingerprint sensor 20. Meanwhile, the vacuum adsorption unit 112 no longer provides the vacuum adsorption efficacy. Then, the fingerprint sensor 20 is removed from the recess 111. Preferably, after the protective layer 301 is cut and trimmed, the air pump 12 provides air to the vacuum adsorption unit 112 through the communication tube 113. The air ejected from the vacuum adsorption unit 112 may directly remove the fingerprint sensor 20 from the recess 111 or facilitate removing the fingerprint sensor 20 from the recess 111.

From the above descriptions, the present invention provides an imprinting system for imprinting a fingerprint sensor and cutting and trimming a protective layer of the fingerprint sensor. After the cutting step and the trimming step are performed, the problems of the conventional fingerprint sensor can be effectively overcome. Since the coating material is coated uniformly, the burred problem is solved and the surface of the protective layer is smoother. Moreover, the fixtures of the imprinting system can perform the coating process and the imprinting process on a single fingerprint sensor or plural fingerprint sensors. Depending on the types of the electronic devices, different types of fingerprint identification modules with one or plural protective layers can be produced according to the practical requirements. Consequently, the technology of the present invention is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A fingerprint sensor imprinting system for imprinting a fingerprint sensor with a top surface and a bottom surface, the fingerprint sensor imprinting system comprising:
a first fixture comprising a first surface, a second surface and at least one opening, wherein the second surface is opposed to the first surface, the at least one opening is formed in the second surface, and the fingerprint sensor is accommodated within the at least one opening;
an imprinting module forming an imprinted layer on the second surface of the first fixture and the top surface of the fingerprint sensor;
a laser cutting module cutting the imprinted layer to define a protective layer on the top surface of the fingerprint sensor, wherein an area of the protective layer is larger than an area of the top surface;
an air pump; and
a second fixture having a recess for accommodating the fingerprint sensor, wherein a vacuum adsorption unit is located at a side of the recess, and the vacuum adsorption unit is connected with the air pump,
wherein after the fingerprint sensor is transferred from the at least one opening of the first fixture to the recess of the second fixture, the air pump is enabled to drive the vacuum adsorption unit to adsorb and fix the fingerprint sensor, and then the protective layer is cut by the laser cutting module, so that the area of the protective layer is equal to the area of the top surface.

2. The fingerprint sensor imprinting system according to claim 1, wherein the at least one opening runs through the first surface and the second surface.

3. The fingerprint sensor imprinting system according to claim 2, wherein the first fixture further comprises an adhesive layer, wherein the adhesive layer is disposed on the first surface, and the bottom surface of the fingerprint sensor is adhered onto the adhesive layer.

4. The fingerprint sensor imprinting system according to claim 1, wherein the imprinted layer is an optically-cured ink layer, a thermally-cured ink layer, a mixed ink layer, a UV-cured resin layer or an anti-fingerprint coating layer.

5. The fingerprint sensor imprinting system according to claim 1, wherein the imprinting module comprises a coating unit and an imprinting unit.

6. The fingerprint sensor imprinting system according to claim 5, wherein the coating unit is a coating knife or a coating roller.

7. The fingerprint sensor imprinting system according to claim 5, wherein the imprinting unit is an imprinting plate or an imprinting roller.

8. A fingerprint sensor imprinting method, comprising steps of:
(a) providing a fingerprint sensor, wherein the fingerprint sensor has a top surface and a bottom surface;
(b) providing a first fixture, wherein the first fixture comprises a first surface, a second surface and at least one opening, wherein the second surface is opposed to the first surface, and the at least one opening is formed in the second surface;
(c) placing the fingerprint sensor within the at least one opening, and forming an imprinted layer on the top surface of the fingerprint sensor and the second surface of the first fixture;
(d) cutting the imprinted layer to define a protective layer, wherein an area of the protective layer is larger than an area of the top surface;
(e) providing a second fixture, wherein the second fixture has a recess, and a vacuum adsorption unit is located at a side of the recess;
(f) transferring the fingerprint sensor to the recess of the second fixture, and driving the vacuum adsorption unit to adsorb and fix the fingerprint sensor; and
(g) cutting the protective layer such that the area of the protective layer is equal to the area of the top surface.

9. The fingerprint sensor imprinting method according to claim 8, wherein in the step (c), an ink material is coated and imprinted on the top surface of the fingerprint, so that the imprinted layer is formed.

10. The fingerprint sensor imprinting method according to claim 9, wherein the ink material is an optically curable ink material, a thermally curable ink material, or a mixed ink material with the optically curable ink material and the thermally curable ink material.

11. The fingerprint sensor imprinting method according to claim 8, wherein in the step (c), a UV-curable resin material is coated and imprinted on the top surface of the fingerprint, so that the imprinted layer is formed.

12. The fingerprint sensor imprinting method according to claim 8, wherein in the step (c), an anti-fingerprint coating is coated and imprinted on the top surface of the fingerprint, so that the imprinted layer is formed.
